(19) United States
(12) Patent Application Publication
(10) Pub. No.: US 2025/0376121 A1
(43) Pub. Date: Dec. 11, 2025

(54) VEHICLE PASSENGER CABIN DISPLAY SYSTEM

(71) Applicant: Ford Global Technologies, LLC, Dearborn, MI (US)

(72) Inventors: Biaohe Guo, Northville, MI (US); Mark Larry, Macomb, MI (US)

(73) Assignee: Ford Global Technologies, LLC, Dearborn, MI (US)

(21) Appl. No.: 18/734,083

(22) Filed: Jun. 5, 2024

(51) Int. Cl. B60R 11/02; B60R 11/00; B60R 13/02; H05K 5/02

(52) U.S. Cl. CPC B60R 11/0235; B60R 13/0212; H05K 5/0217; B60R 2011/0092; B60R 2011/0276

(57) ABSTRACT

A display system for a passenger cabin of a vehicle has a seating area and a liftgate opening. The display system includes a flexible display screen having a front side for displaying images. A transport assembly is configured to be mounted proximate a headliner of the passenger cabin over the seating area. The transport assembly includes a motorized carrier coupled to the flexible display screen. The motorized carrier is configured to move the flexible display screen to a first viewing position hanging from a forward end of the transport assembly. The flexible display screen is moveable to a second viewing position hanging vertically from a rearward end of the transport assembly and is further moveable to a third viewing position on the transport assembly and viewable above the seating area.

### FIELD OF THE DISCLOSURE

The present disclosure generally relates to video displays deployed in the passenger cabin of motor vehicles, and more particularly relates to a vehicle interior mounted flexible display system having multiple deployable viewing positions.

### BACKGROUND OF THE DISCLOSURE

Motor vehicles have increasingly employed video displays in the passenger cabin. For example, video displays may be located in front of a passenger seat for forward viewing by a passenger seated therein. It may be desirable to provide for a display system in a vehicle that is deployable to multiple viewing positions.

### SUMMARY OF THE DISCLOSURE

According to a first aspect of the present disclosure, a display system for a passenger cabin of a vehicle has a seating area and a liftgate opening. The display system includes a flexible display screen having a front side for displaying images and an opposite back side. A transport assembly is configured to be mounted proximate a headliner of the passenger cabin over the seating area. The transport assembly includes a motorized carrier coupled to the flexible display screen. The motorized carrier is configured to move the flexible display screen to a first viewing position hanging from a forward end of the transport assembly. The flexible display screen is moveable to a second viewing position hanging vertically from a rearward end of the transport assembly and is further moveable to a third viewing position on the transport assembly and viewable above the seating area.

Embodiments of the first aspect of the present disclosure can include any one or a combination of the following features:
the first viewing position is generally forward of a seat, the second position is generally rearward of the seat, and the third position is generally above the seat;
the flexible display screen has an opaque film on the back side;
the flexible display screen is generally viewable in the second position from a rear end of the vehicle when a liftgate is opened;
the transport assembly comprises a winder for winding and unwinding the flexible display screen;
the transport assembly further comprises a toggle structure moveable between a first arrangement that guides the flexible display screen to the first position and a second arrangement that guides the flexible display screen to the second position;
the transport assembly further comprises a moveable carrier track for moving the flexible display screen between the first, second and third viewing positions;
the transport assembly comprises a moveable carrier track for transporting the flexible display screen amongst the first, second and third viewing positions;
the moveable track further comprises a magnet, wherein a polarity of the magnet is controlled to attract to a ferromagnetic metal on the flexible display screen or to repel the ferromagnetic metal on the display screen to control movement of the flexible display screen;
the magnet attaches to the ferromagnetic metal to hold the flexible display screen on the moveable track and repels to ferromagnetic metal to release the flexible display screen to the second viewing position; and
the flexible display screen comprises a plurality of interconnected bars.

According to a second aspect of the present disclosure, a vehicle has a body configured to include a passenger cabin having a seating area, a headliner and a liftgate opening. The display system is proximate the headliner. The display system includes a flexible display screen having a front side for displaying images and an opposite back side and a transport assembly mounted proximate the headliner. The transport assembly includes a motorized carrier coupled to the flexible display screen. The motorized carrier is configured to move the flexible display screen to a first viewing position hanging from a forward end of the transport assembly. The flexible display screen is moveable to a second viewing position hanging vertically from a rearward end of the transport assembly and is further moveable to a third viewing position on the transport assembly and viewable above the seating area.

Embodiments of the second aspect of the present disclosure can include any one or a combination of the following features:
the first viewing position is generally forward of a seat, the second viewing position is generally rearward of the seat, and the third viewing position is generally above the seat;
the flexible display screen has an opaque film on the back side;
the flexible display screen is generally viewable in the second viewing position from a rear end of the vehicle when a liftgate is opened;
the transport assembly comprises a winder for winding and unwinding the flexible display screen;
the transport assembly further comprises a toggle structure moveable between a first arrangement that guides the flexible display screen to the first viewing position and a second arrangement that guides the flexible display screen to the second viewing position;
the transport assembly further comprises a moveable track for moving the flexible display screen between the first, second and third viewing positions;
the transport assembly comprises a moveable track, and wherein the moveable track further comprises a magnet, wherein a polarity of the magnet is controlled to attract to a ferromagnetic metal on the flexible display screen or to repel the ferromagnetic metal on the display screen to control movement of the flexible display screen;
the magnet attracts to the ferromagnetic metal to hold the flexible display screen on the moveable track and repels the ferromagnetic metal to release the flexible display screen to the second viewing position.

These and other features, advantages, and objects of the present disclosure will be further understood and appreciated by those skilled in the art by reference to the following specification, claims, and appended drawings.

### BRIEF DESCRIPTION OF THE DRAWINGS

In the drawings:

FIG. 1 is a schematic side view of a motor vehicle with a display system having a deployable display screen in the passenger cabin, according to one example;

FIG. 2 is a rear perspective view of a rear end of the motor vehicle with the lift gate open and the flexible display screen in a rear viewing position viewable from the rear end of the motor vehicle;

FIG. 3 is a schematic side view of the flexible display screen showing the layers of the flexible display screen, according to one example;

FIG. 4 is a schematic side view of the flexible display system having a transport assembly with a winder and a toggle mechanism, according to a first embodiment;

FIG. 4A is an elevated perspective view of the display system showing the flexible display screen in a first viewing position which is generally forward of a rear seat in the passenger cabin;

FIG. 5 is a schematic side view of the display system illustrating the flexible display screen in a second viewing position generally above the rear seat proximate the headliner;

FIG. 5A is a lower perspective view of the display system in the second position as seen in FIG. 5;

FIG. 6 is a schematic side view of the flexible display system illustrating the flexible display screen in a third position generally viewable rearward of the rear seat;

FIG. 6A is an upper perspective view of the flexible display system with the flexible display screen in the third position as shown in FIG. 6;

FIG. 6B is an upper perspective view of the display system with the flexible display screen in a stowed position wound up on the winder;

FIG. 7A is an upper perspective view of the display system showing the flexible display screen in the first viewing position, according to a second embodiment;

FIG. 7B is an upper perspective view of the display system shown in FIG. 7A with the flexible display screen in the second position generally above the rear seat proximate the headliner;

FIG. 7C is an upper perspective view of the display system shown in FIG. 7A with the flexible display screen in the stowed position;

FIG. 7D is an upper perspective view of the display system shown in FIG. 7A with the flexible display screen in the third viewing position;

FIG. 8 is an upper perspective view of the moveable track system transporting a flexible display screen having hingedly connected panels, according to another example; and

FIG. 9 is an upper perspective view of the display system having a flexible display screen with metal panels on opposite lateral sides, according to a further example.

### DETAILED DESCRIPTION OF PREFERRED EMBODIMENTS

Reference will now be made in detail to the present preferred embodiments of the disclosure, examples of which are illustrated in the accompanying drawings. Wherever possible, the same reference numerals will be used throughout the drawings to refer to the same or like parts. In the drawings, the depicted structural elements are not to scale and certain components are enlarged relative to the other components for purposes of emphasis and understanding.

As required, detailed embodiments of the present disclosure are disclosed herein; however, it is to be understood that the disclosed embodiments are merely exemplary of the disclosure that may be embodied in various and alternative forms. The figures are not necessarily to a detailed design; some schematics may be exaggerated or minimized to show function overview. Therefore, specific structural and functional details disclosed herein are not to be interpreted as limiting, but merely as a representative basis for teaching one skilled in the art to variously employ the present disclosure.

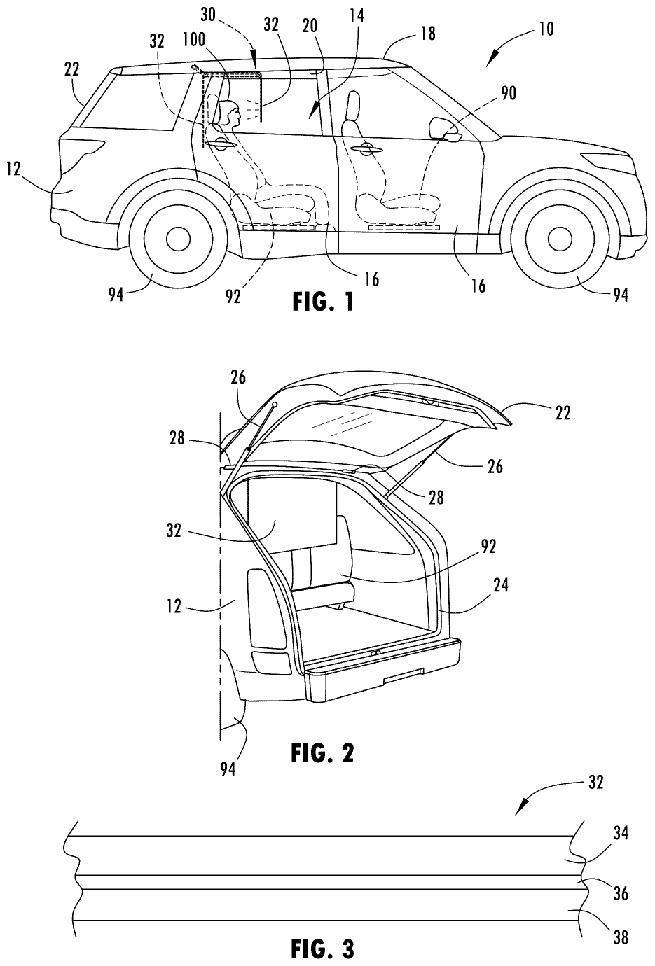

For purposes of description herein, the terms “upper,” “lower,” “right,” “left,” “rear,” “front,” “vertical,” “horizontal,” and derivatives thereof shall relate to the concepts as oriented in FIG. 1. However, it is to be understood that the concepts may assume various alternative orientations, except where expressly specified to the contrary. It is also to be understood that the specific devices and processes illustrated in the attached drawings, and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise.

The present illustrated embodiments reside primarily in combinations of method steps and apparatus components related to a deployable display system for a vehicle passenger cabin and vehicle having the deployable display system. Accordingly, the apparatus components and method steps have been represented, where appropriate, by conventional symbols in the drawings, showing only those specific details that are pertinent to understanding the embodiments of the present disclosure so as not to obscure the disclosure with details that will be readily apparent to those of ordinary skill in the art having the benefit of the description herein. Further, like numerals in the description and drawings represent like elements.

As used herein, the term “and/or,” when used in a list of two or more items, means that any one of the listed items can be employed by itself, or any combination of two or more of the listed items, can be employed. For example, if a composition is described as containing components A, B, and/or C, the composition can contain A alone; B alone; C alone; A and B in combination; A and C in combination; B and C in combination; or A, B, and C in combination.

In this document, relational terms, such as first and second, top and bottom, and the like, are used solely to distinguish one entity or action from another entity or action, without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises . . . a” does not, without more constraints, preclude the existence of additional identical elements in the process, method, article, or apparatus that comprises the element.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an end-point of a range, the disclosure should be understood to include the specific value or end-point referred to. Whether or not a numerical value or end-point of a range in the specification recites “about,” the numerical value or end-point of a range is intended to include two embodiments: one modified by “about,” and one not modified by “about.” It will be further understood that the end-points of each of the ranges are significant both in relation to the other end-point, and independently of the other end-point.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

As used herein the terms “the,” “a,” or “an,” mean “at least one,” and should not be limited to “only one” unless explicitly indicated to the contrary. Thus, for example, reference to “a component” includes embodiments having two or more such components unless the context clearly indicates otherwise.

Referring to FIGS. 1 and 2, a wheeled automotive or motor vehicle 10 is generally illustrated configured with passenger seating for transporting one or more passengers on board the motor vehicle 10. The motor vehicle 10 has a plurality of road wheels 94 and a vehicle body 12 that generally defines a passenger cabin 14 having a seating area. The vehicle body 12 generally includes body panels, doors 16, a roof 18 and a rear liftgate 22. The passenger cabin 14 may contain various features and trim components. The passenger cabin 14 is shown having an arrangement of front row passenger seats 90, which typically may include a driver's seat and a passenger seat. The motor vehicle 10 is also illustrated having additional seating in a second row of seating as shown by seat 92 which is in the seating area. The second row seating, including seat 92 which is shown occupied by a passenger 100, is located vehicle rearward of the first row of seating that includes vehicle seat 90. The motor vehicle 10 may include additional rows of seating as is common for a large van or bus, for example. It should be appreciated that the motor vehicle 10 may be a motor vehicle such as a wheeled car, truck, SUV, van or bus, for example, or an airplane, train, boat or other vehicle capable of transporting one or more passengers.

The second row of seating, which includes seat 92 in the seating area, may include one or more captain's seats, a split seat, such as a 40/60 split bench seat, or a bench seat, according to a few examples. The passenger cabin 14 generally has a seating area with seat 92 for seating the passenger 100 shown seated upon seat 92. The seat 92 may be positioned on either end of the row of seating or in the middle of the row of seating.

The motor vehicle 10 is further shown equipped with a video display system 30 which is generally located within or proximate to a headliner 20 below the roof 18 of the motor vehicle 10. The video display system 30 is generally located above the seat 92 in the second row of seating and is therefore above the seating area. The video display system 30 is a deployable video display system that is controlled to deploy a flexible display screen 32 to one of a plurality of positions. The plurality of positions includes a first viewing position presented generally forward of the user 100 seated in seat 92 as shown in FIG. 1. The video display system 30 may further deploy the flexible display screen 32 to a second viewing position generally extending horizontally above the user 100 seated in seat 92 of the seating area. The video display system 30 may further deploy the flexible display screen 32 to a third viewing position rearward of the user 100 seated in seat 92 and viewable from a rear end of the motor vehicle 10 when the liftgate 22 is in the open position as seen in FIG. 2.

The motor vehicle 10 shown in FIG. 2 has the liftgate 22 at the rear end of the motor vehicle 10. The liftgate 22 may be actuated via actuator rods 26 and pivots on the top edge about hinges 28 between an open position that exposes the rear opening as seen in FIG. 2 and a closed position that closes the rear opening 24. When the liftgate 22 is in the open position and the video display system 30 is configured with the flexible display screen 32 in the third viewing position, the flexible display screen 32 may be viewed from the rear end of the motor vehicle 10 looking into the rear opening 24. As such, the flexible display screen 32 in the third viewing position may serve as a tailgate display viewable by users outside the motor vehicle 10 when the motor vehicle 10 is in Park and not moving.

The flexible display screen 32 is illustrated in one example in FIG. 3 made up of layers. The flexible display screen 32 is flexible and rollable and has a flexible display film 34 on the front side, a flexible back film 38 on the opposite back side, and an adhesive layer 36 in between display film 34 and back film 38 adhering the flexible display film 34 onto the back film 38. The back film 38 may be a black or opaque film, for example. As such, the flexible display screen 32 is configured to display images emitted on the front side of the flexible display film 34 and prevents images from viewing on the back side. Examples of the flexible display film include liquid crystal displays (LCD) using organic flexible substrates, organic light emitting diodes (OLED) and micro-LED displays. It should be appreciated that the flexible display screen 32 is flexible and rollable such that it may bend sufficient to be rolled and wound onto a winder or rolled and wound around a portion of an endless belt.

According to another example, the flexible display screen 32 may employ a switchable display film as the back film 38 which may be switchable between a transparent film and an opaque film. A switchable display film is a film that can be controlled electrically to switch between a transparent mode and an opaque mode. The flexible display screen 32 may show images on the front side with high image clarity and may also show images on the back with relatively lower image clarity. Examples of switchable display film technologies may include polymer-dispersed liquid crystal (PDLC), suspended particle devices (SPD), electrochromic (EC) and electrophoretic technologies.

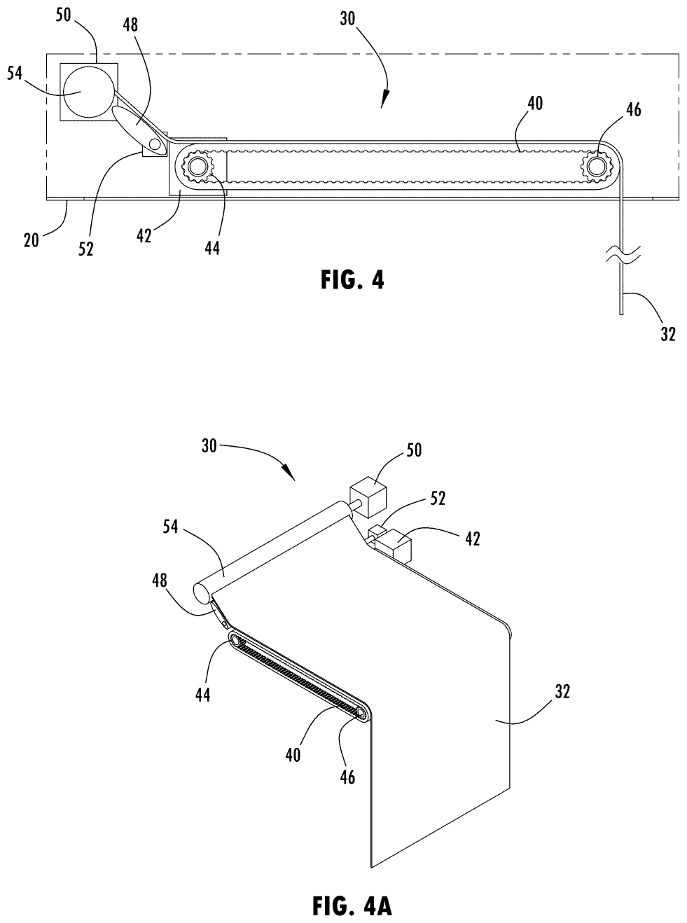

Referring to FIGS. 4-6B, the display system 30 is shown according to a first embodiment. In this embodiment, the display system 30 includes the flexible display screen 32 operatively coupled to a transport assembly which is configured to be mounted proximate to the headliner 20 of the passenger cabin 14 over the seating area. The transport assembly includes a motorized carrier track 40 coupled to the flexible display screen 32. The carrier track 40 is configured to move the flexible display screen to the first viewing position hanging from a forward end of the transport assembly, and the flexible display screen 32 is movable to a second viewing position on the transport assembly and viewable above the seating area, and is further moveable to a third viewing position hanging vertically from a rearward end of the transport assembly.

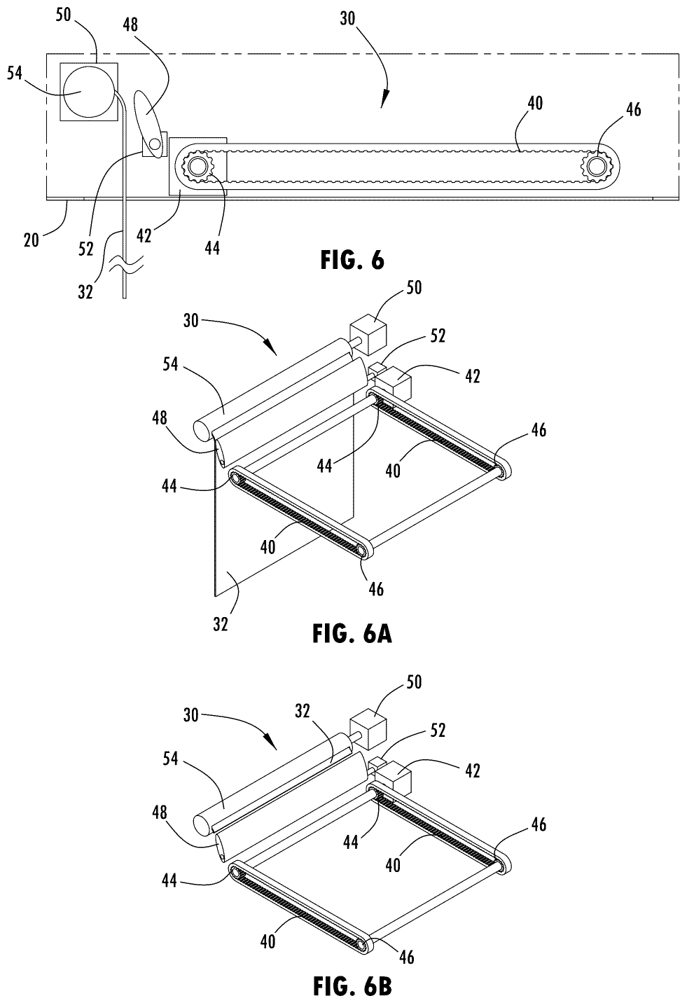

In the first embodiment, the transport assembly includes a winder 54 in the form of a rolling display scroll or roller for winding and unwinding the flexible display screen 32. The winder 54 includes an actuator 50 in the form of a motor for rotating the winder 54. In addition, the transport assembly includes the movable carrier track 40 which is shown as an endless track having a pair of parallel belts 40A and 40B spaced apart and mounted around a drive axle 44 and a follower axle 46 on opposite ends. The movable carrier track 40 may rotate clockwise or counterclockwise when actuated by the motor 42. The transport assembly further includes a toggle structure 48 movable between a first arrangement that guides the flexible display screen 32 to the first viewing position and a second arrangement that guides the flexible display screen 32 to the second viewing position. The toggle structure 48 may include an actuator 52 in the form of a motor that rotates to move the toggle structure 48 from the position shown in FIG. 4, which guides the flexible display screen 32 to move to the first viewing position clockwise to the position shown in FIG. 6 in which the flexible display screen 32 is allowed to hang in the third viewing position. Electrical power and video or displayed content may be supplied to the flexible display screen 32 in the end connected to the winder 54.

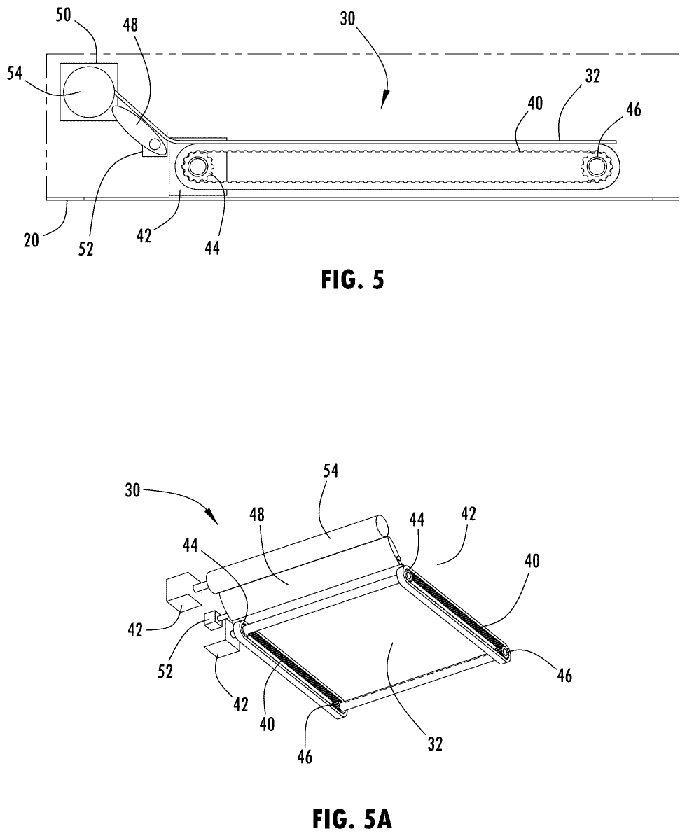

In operation, the flexible display screen 32 is actuatable to the first viewing position as shown in FIGS. 4 and 4A in which the flexible display screen 32 is presented generally forward of the seating area and extends or hangs downward from a forward end of the transport assembly. The flexible display screen 32 may be moved and extended vertically downward to the first viewing position by unwinding the flexible display screen 32 from the winder 54. In order to move the flexible display screen 32 to another position, the winder 54 rotates counterclockwise to wind the flexible display screen 32 at least partially onto the winder 54. This may include partially winding the flexible display screen 32 to move to the second viewing position shown on top of the carrier track 40 as illustrated in FIGS. 5A and 5B. In this second viewing position, the flexible display screen 32 is located in a viewable overhead position extending horizontally within an open region or below the headliner 20 seen when viewing above the seat 92 and the seating area. As seen in FIG. 5A, the flexible display screen 32 is viewed in the overhead region between the drive and follower axles 44 and 46 in the one dimension, and between the left and right track belts 40A and 40B in the perpendicular orientation. As such, a passenger seated in the seat 92 may look upward towards the headliner 20 and roof 18 to view the flexible display screen 32 in the second viewing position.

In order to move the flexible display screen 32 to the third viewing position that is viewable behind the seating area of seat 92 and generally viewable from the opening at the rear end of the motor vehicle 10 with the tailgate 22 in the open position, the winder 54 continues to wind the flexible display screen 32 onto the winder 54 to what may be referred to as a stowed position as seen in FIG. 6B. In this position, a substantial portion such as nearly all of the flexible display screen 32 is fully wound onto the winder 54. When the length of the flexible display screen 32 is sufficiently short such that the end of the flexible display screen 32 passes by the toggle structure 48, the toggle structure 48 is rotated clockwise to move to the second position as seen in FIGS. 6 and 6A. In this position, the toggle structure 48 is positioned to not engage the flexible display screen 32. The flexible screen display screen 32 is thus able to hang vertically downward from the rear end of the transport assembly downward in the third viewing position.

With the flexible display screen 32 in the third viewing position, the flexible display screen 32 may be moved back to the stowed position by winding up the winder 54 to the position shown in FIG. 6B. The flexible display screen 32 may further be repositioned onto the transport assembly by actuating the toggle structure 48 counterclockwise back to the first position which will act to guide the flexible display screen 32 when the winder 54 unwinds the flexible display screen 32 and to guide the flexible display screen 32 back onto the transport carrier track which may be actuated to move the flexible display screen 32 to be positioned in either the second viewing position or further extended to the first viewing position.

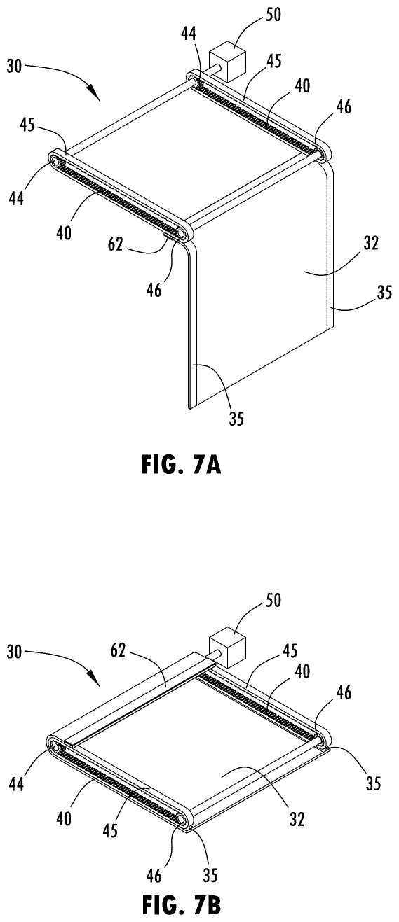

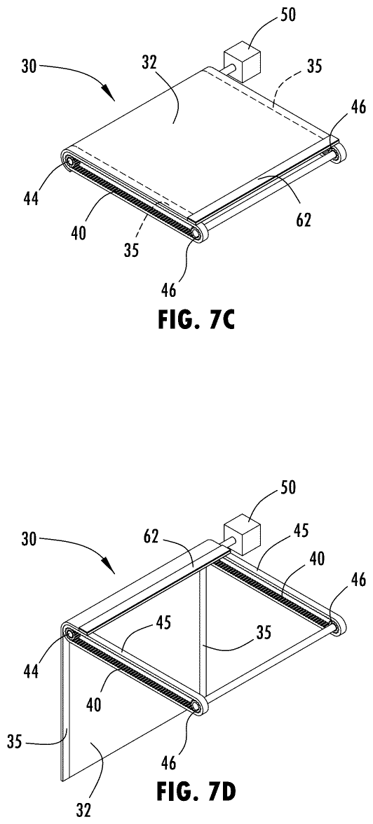

Referring to FIGS. 7A-7D, a display system 30 is shown having a transport assembly, according to a second embodiment. In this embodiment, the flexible display screen 32 has a first end with an electronics control module 62 connected to the pair of belts 40A and 40B on the moveable carrier track 40. The electronics module may include circuitry to acquire the power and video or display content via wired or wireless communication to the flexible display screen 32. Similar to the first embodiment, the moveable track 40 has an actuator 50, such as a motor, for driving the drive axle 44 which is operable with the follower axle 46 to move an endless belt in the clockwise or counterclockwise directions. In this embodiment, the flexible display screen 32 has a ferromagnetic metal 35 located on the lateral edges on opposite sides, and the outer surface of each of the endless belts 40A and 40B has a magnet 45. The magnet 45 may be controlled to provide a first polarity to attract the metal 35 on the flexible display screen 32 or a second opposite polarity to repel the ferromagnetic metal 35 on the display screen 32. Electrical circuitry and controls may be provided in the electronics control module 62 to control the polarity of the magnet 45. With the polarity of the magnets 45 set to attract to the ferromagnetic metal 35 on the belts 40A and 40B, the flexible display screen 32 may be wound onto the belts 40A and 40B to a second position as seen in FIG. 7B which is a second viewing position viewable above the seating area and the seat 92. The flexible display screen 32 may be further wound clockwise onto the belts 40A and 40B using magnetic attraction to the stowed position seen in FIG. 7C, in which the flexible display screen 32 is held in the stowed position. In order to move the flexible display screen 32 to the third viewing position as seen in FIG. 7D, the polarity of the magnets 45 is switched to cause the magnets 45 to repel the ferromagnetic metal 35 on the edges of the flexible display screen 32. This may occur when the transport assembly rotates the belts 40A and 40B in the counterclockwise direction to allow the flexible display screen 32 to release and hang vertically downward from the rear end of the belts 40A and 40B, as seen in FIG. 7D.

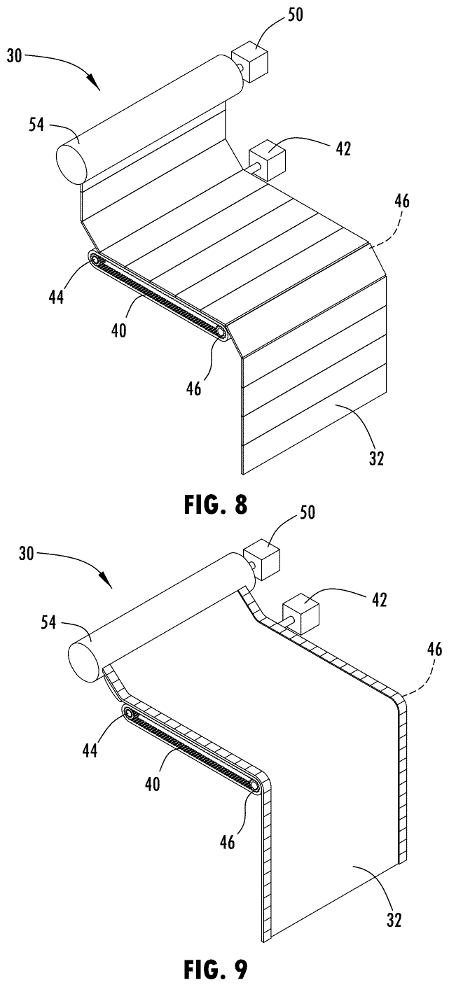

Referring to FIG. 8, another example of a flexible display screen 32 is illustrated having a plurality of hingedly connected panels. The hingedly connected panels pivot relative to one another to allow the display screen to be flexible. It should be appreciated that the size and separation distance of the hingedly connected panels may be such that it may sufficiently roll and wind onto the winder 54 as seen in FIG. 8.

Referring to FIG. 9, an alternate embodiment of a flexible display screen 32 is seen having a flexible display film in the middle viewing area and rigid hinge bars on the left and right sides. As such, the left and right edges of the flexible display screen 32 are hingedly connected together, whereas the middle viewing area is open for displaying the video images.

Accordingly, a display system 30 having a flexible display screen 32 is provided for a passenger cabin of a vehicle 10 having a seating area and a liftgate opening. The display system 30 is advantageously provided proximate to a headliner 20 in the vehicle 10 to provide for a first viewing position in front of the seating area, a second viewing position above the seating area, and a third viewing position behind the seating area and generally viewable through rear opening 24 when the liftgate 22 is in the open position.

It is to be understood that variations and modifications can be made on the aforementioned structure without departing from the concepts of the present disclosure, and further it is to be understood that such concepts are intended to be covered by the following claims unless these claims by their language expressly state otherwise.

What is claimed is:

1. A display system for a passenger cabin of a vehicle having a seating area and a liftgate opening, the display system comprising:
a flexible display screen having a front side for displaying images and an opposite back side; and
a transport assembly configured to be mounted proximate a headliner of the passenger cabin over the seating area, wherein the transport assembly includes a motorized carrier coupled to the flexible display screen, wherein the motorized carrier is configured to move the flexible display screen to a first viewing position hanging from a forward end of the transport assembly, and wherein the flexible display screen is moveable to a second viewing position hanging vertically from a rearward end of the transport assembly and is further moveable to a third viewing position on the transport assembly and viewable above the seating area.

2. The display system of claim 1, wherein the first viewing position is generally forward of a seat, the second position is generally rearward of the seat, and the third position is generally above the seat.

3. The display system of claim 1, wherein the flexible display screen has an opaque film on the back side.

4. The display system of claim 1, wherein the flexible display screen is generally viewable in the second position from a rear end of the vehicle when a liftgate is opened.

5. The display system of claim 1, wherein the transport assembly comprises a winder for winding and unwinding the flexible display screen.

6. The display system of claim 5, wherein the transport assembly further comprises a toggle structure moveable between a first arrangement that guides the flexible display screen to the first position and a second arrangement that guides the flexible display screen to the second position.

7. The display system of claim 5, wherein the transport assembly further comprises a moveable carrier track for moving the flexible display screen between the first, second and third viewing positions.

8. The display system of claim 1, wherein the transport assembly comprises a moveable carrier track for transporting the flexible display screen amongst the first, second and third viewing positions.

9. The display system of claim 8, wherein the moveable track further comprises a magnet, wherein a polarity of the magnet is controlled to attract to a ferromagnetic metal on the flexible display screen or to repel the ferromagnetic metal on the display screen to control movement of the flexible display screen.

10. The display system of claim 9, wherein the magnet attaches to the ferromagnetic metal to hold the flexible display screen on the moveable track and repels to ferromagnetic metal to release the flexible display screen to the second viewing position.

11. The display system of claim 1, wherein the flexible display screen comprises a plurality of interconnected bars.

12. A vehicle comprising:
a body configured to include a passenger cabin having a seating area, a headliner and a liftgate opening; and
a display system proximate the headliner, the display system comprising:
a flexible display screen having a front side for displaying images and an opposite back side; and
a transport assembly mounted proximate the headliner, wherein the transport assembly includes a motorized carrier coupled to the flexible display screen, wherein the motorized carrier is configured to move the flexible display screen to a first viewing position hanging from a forward end of the transport assembly, wherein the flexible display screen is moveable to a second viewing position hanging vertically from a rearward end of the transport assembly, and is further moveable to a third viewing position on the transport assembly and viewable above the seating area.

13. The vehicle of claim 12, wherein the first viewing position is generally forward of a seat, the second viewing position is generally rearward of the seat, and the third viewing position is generally above the seat.

14. The display system of claim 12, wherein the flexible display screen has an opaque film on the back side.

15. The display system of claim 12, wherein the flexible display screen is generally viewable in the second viewing position from a rear end of the vehicle when a liftgate is opened.

16. The display system of claim 12, wherein the transport assembly comprises a winder for winding and unwinding the flexible display screen.

17. The display system of claim 16, wherein the transport assembly further comprises a toggle structure moveable between a first arrangement that guides the flexible display screen to the first viewing position and a second arrangement that guides the flexible display screen to the second viewing position.

18. The display system of claim 16, wherein the transport assembly further comprises a moveable track for moving the flexible display screen between the first, second and third viewing positions.

19. The display system of claim 18, wherein a polarity of the magnet is controlled to attract to a ferromagnetic metal on the flexible display screen or to repel the ferromagnetic metal on the display screen to control movement of the flexible display screen.

20. The display system of claim 19. wherein the magnet attracts to the ferromagnetic metal to hold the flexible display screen on the moveable track and repels the ferromagnetic metal to release the flexible display screen to the second viewing position.
